(19) United States
(12) Patent Application Publication
(10) Pub. No.: US 2025/0324584 A1
(43) Pub. Date: Oct. 16, 2025

(54) SEMICONDUCTOR DEVICE AND METHOD OF FABRICATING THE SAME

(71) Applicant: MACRONIX International Co., Ltd., Hsinchu (TW)

(72) Inventors: Kuan-Yuan Shen, Hsinchu County (TW); Teng-Hao Yeh, Hsinchu City (TW); Guan-Ru Lee, Hsinchu City (TW)

(73) Assignee: MACRONIX International Co., Ltd., Hsinchu (TW)

(21) Appl. No.: 18/632,293

(22) Filed: Apr. 11, 2024

(51) Int. Cl. H10B 41/27; H10B 41/35

(52) U.S. Cl. CPC H10B 41/27; H10B 41/35

(57) ABSTRACT

A semiconductor device includes a substrate. A first gate stack structure is located on the substrate in a first region. A second gate stack structure is located on the substrate in a second region. A third gate stack structure is located on the substrate in a third region. A thickness of the first gate dielectric layer of the first gate stack structure is greater than a thickness of the second gate dielectric layer of the second gate stack structure. The thickness of the second gate dielectric layer is greater than a thickness of the third gate dielectric layer of the third gate stack structure. Thicknesses of the first gate layer and the second gate layer are respectively greater than a thickness of the third gate layer. Embodiments of the present disclosure may be applied to 3D AND flash memory.

### BACKGROUND

### Field of the Disclosure

The present disclosure relates to an integrated circuit and a method of fabricating the same, and in particular, to a semiconductor device and a method of fabricating the same.

### Description of Related Art

Metal oxide semiconductor devices are often adopted in the peripheral areas of various memory devices. Metal oxide semiconductor devices in the peripheral area normally require gate dielectric layers of various thicknesses to meet different voltage requirements. However, for gate dielectric layers with various thicknesses, loss of thickness often occurs due to etching or the thickness is increased due to thermal oxidation in the manufacturing process, it is difficult to accurately control the thickness of gate dielectric layer.

### SUMMARY OF THE DISCLOSURE

The present disclosure provides a semiconductor device that may avoid the thickness loss of the gate dielectric layer that is already formed, and accurately form various gate dielectric layers with very large thickness differences.

In an embodiment of the disclosure, a semiconductor device includes a substrate, a first gate stack structure, a second gate stack structure and a third gate stack structure. The substrate includes a first region, a second region and a third region. A first gate stack structure is located on the substrate in the first region and includes a first gate layer and a first gate dielectric layer. A second gate stack structure is located on the substrate in the second region and includes a second gate layer and a second gate dielectric layer. The third gate stack structure is located on the substrate in the third region, and includes a third gate layer and a third gate dielectric layer. A thickness of the first gate dielectric layer is greater than a thickness of the second gate dielectric layer. The thickness of the second gate dielectric layer is greater than a thickness of the third gate dielectric layer. Thicknesses of the first gate layer and the second gate layer are respectively greater than a thickness of the third gate layer.

A method for fabricating a semiconductor device according to an embodiment of the present disclosure includes the following steps: providing a substrate, the substrate includes a first region, a second region and a third region; forming a first gate dielectric layer on the substrate in the first region; forming a second gate dielectric layer on the substrate in the second region and the third region; forming a buffer layer on the first gate dielectric layer in the first region and on the second gate dielectric layer in the second region; forming a third gate dielectric layer on the substrate in the third region; forming a conductive layer on the buffer layer in the first region and the second region and the third gate dielectric layer in the third region; patterning the conductive layer and the buffer layer to form a gate layer in the first region; forming a second gate layer in the second region; and forming a third gate layer in the third region.

Based on the above, the present disclosure may avoid the thickness loss of the gate dielectric layer that is already formed during the manufacturing process, and accurately form several types of gate dielectric layers with very large thickness differences. In addition, embodiments of the present disclosure may also be integrated with the self-aligned shallow trench isolation structure process and reduce the number of chemical mechanical polishing processes to reduce manufacturing costs.

### BRIEF DESCRIPTION OF THE DRAWINGS

FIG. 1A to FIG. 1K show a schematic cross-sectional view of a method of fabricating a semiconductor device according to the first embodiment of the present disclosure.

FIG. 2A to FIG. 2H show a schematic cross-sectional view of a method of fabricating a semiconductor device according to the second embodiment of the present disclosure.

FIG. 3A to FIG. 3J show a schematic cross-sectional view of a method of fabricating a semiconductor device according to the third embodiment of the present disclosure.

FIG. 4A to FIG. 4H show a schematic cross-sectional view of a method of fabricating a semiconductor device according to the fourth embodiment of the present disclosure.

### DESCRIPTION OF EMBODIMENTS

In the embodiments of the present disclosure, a semiconductor device having gate dielectric layers with multiple (e.g., two or three) thicknesses may be formed for application in high voltage (HV) devices, low voltage (LV) devices, and extra low voltage (LLV) devices which have different operating voltages. Among them, the thickness of the gate dielectric layer of high-voltage (HV) devices is the thickest, and the thickness of the gate dielectric layer of ultra-low voltage (LLV) devices is the thinnest. In the embodiments of the present invention, the gate dielectric layer with the smallest thickness may be formed very thin.

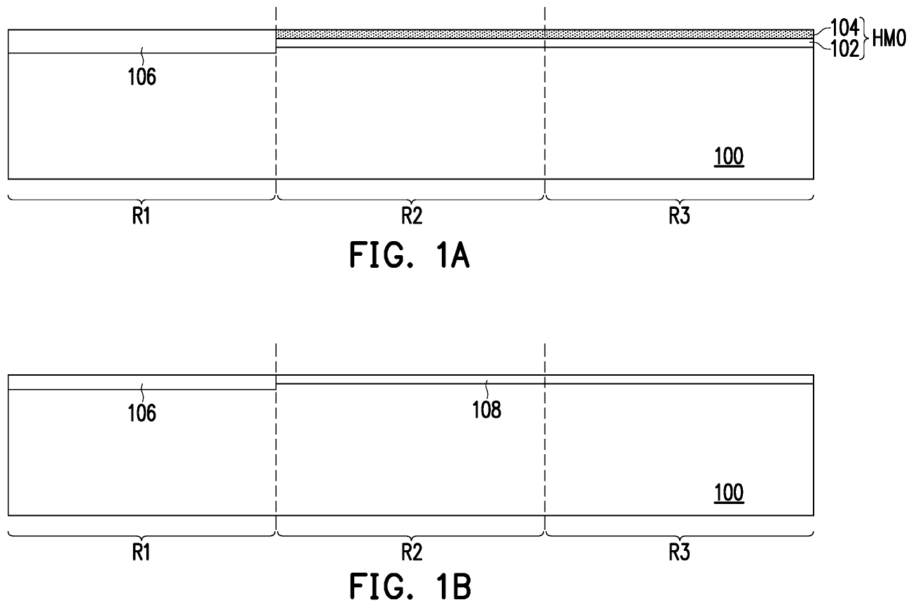

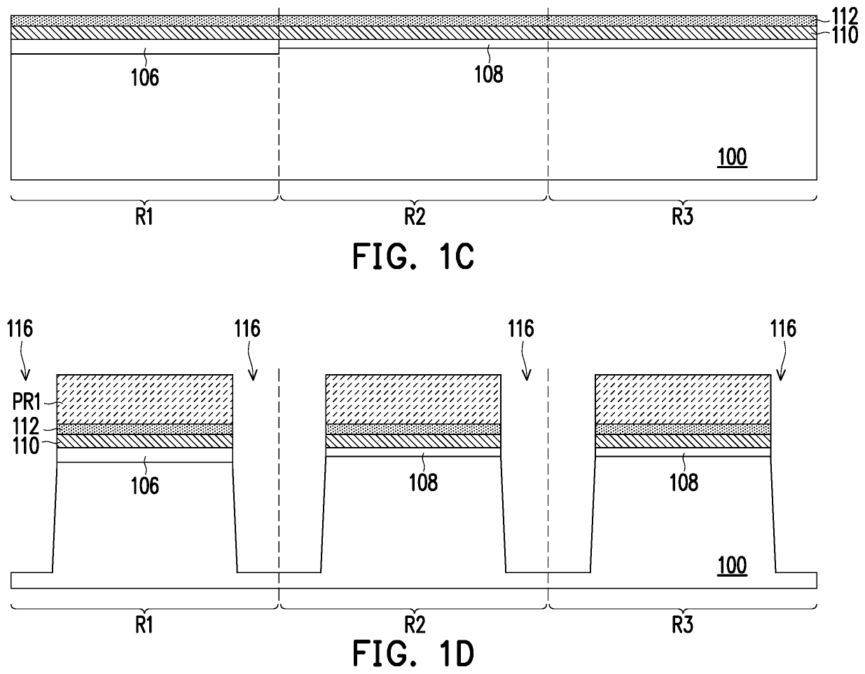

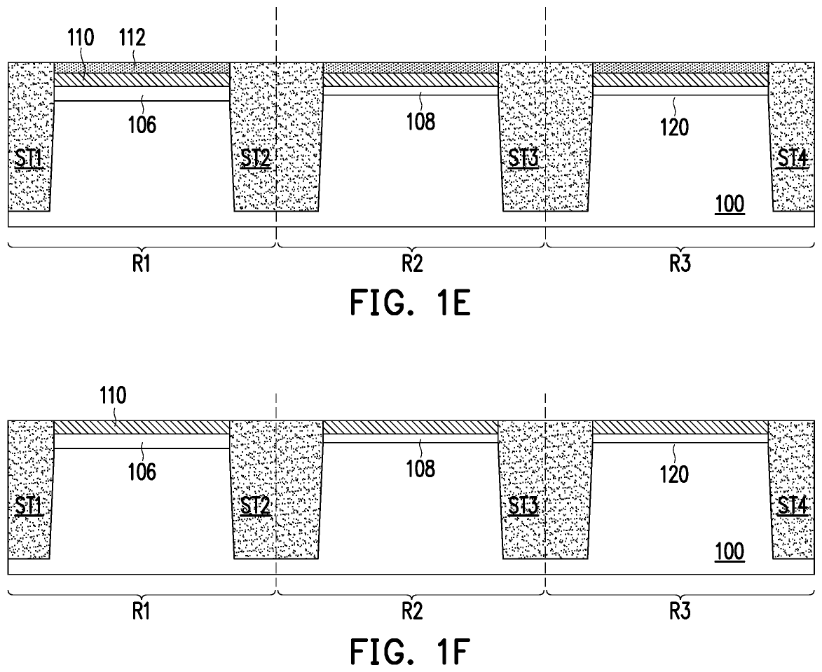

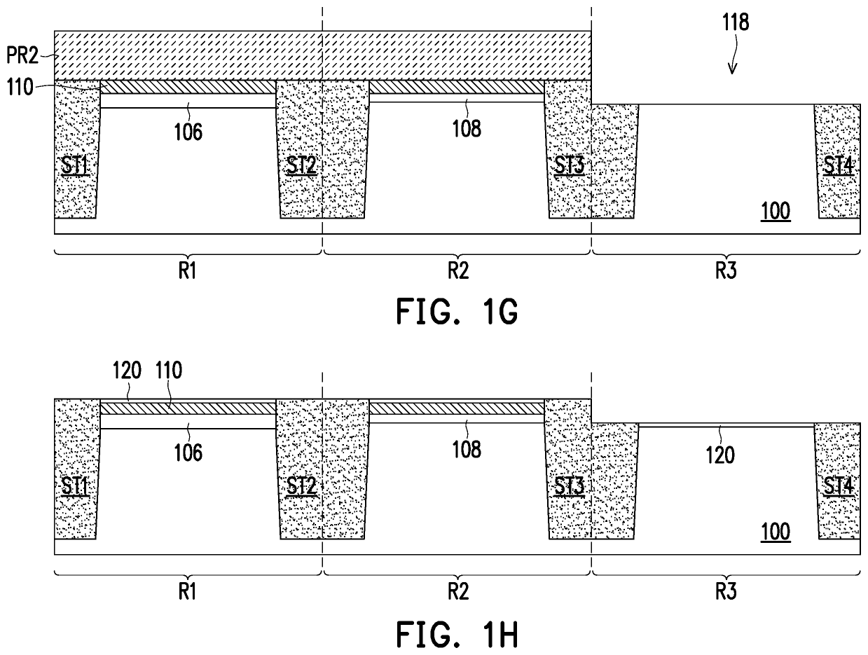

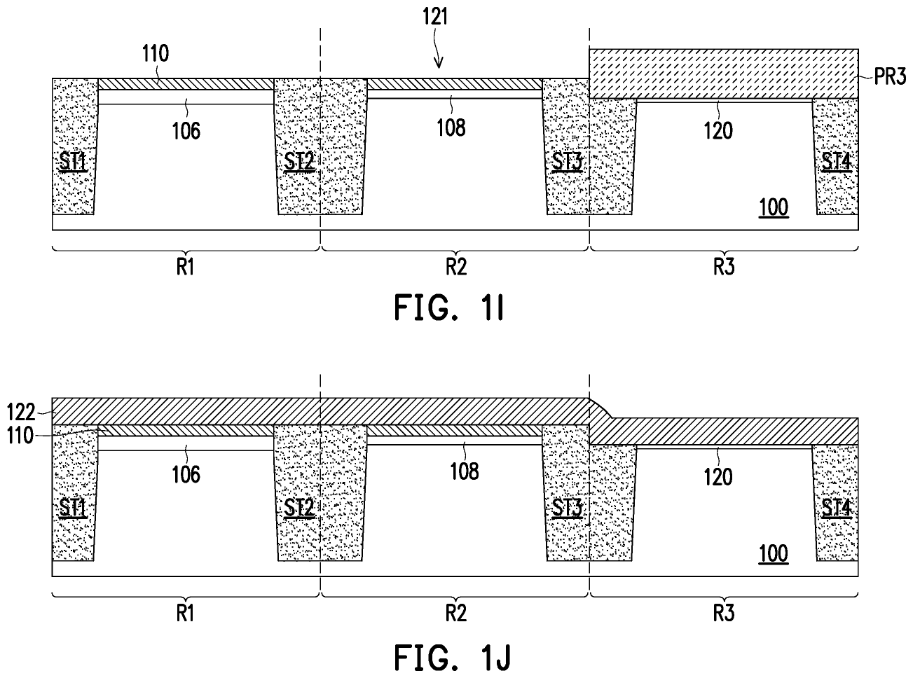

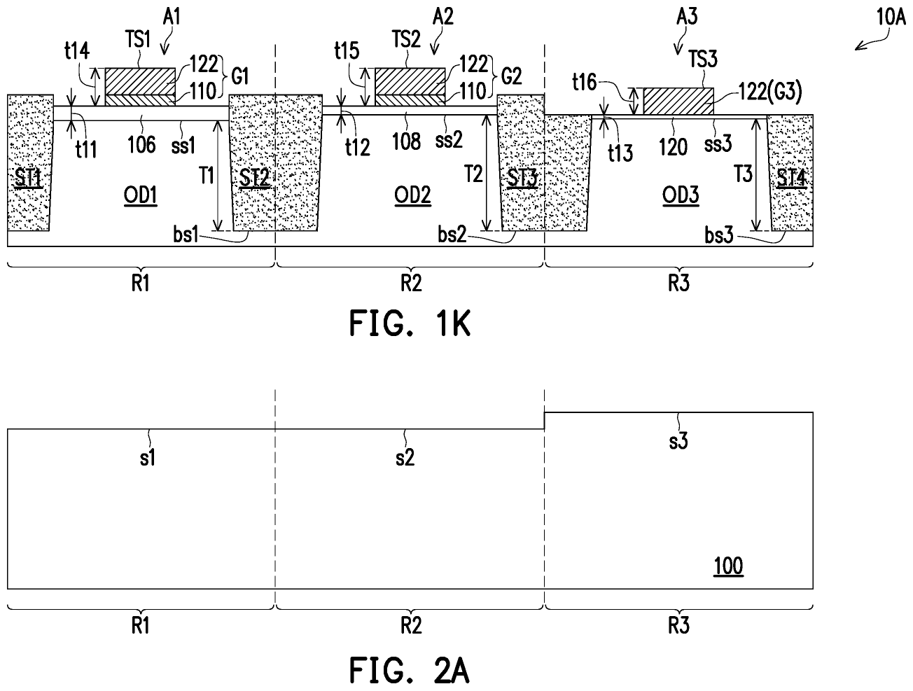

FIG. 1A to FIG. 1K show a schematic cross-sectional view of a method of fabricating a semiconductor device according to the first embodiment of the present disclosure.

Referring to FIG. 1A, a substrate 100 is provided. The substrate 100 may be a semiconductor substrate, such as a silicon substrate. The substrate 100 includes a first region R1, a second region R2, and a third region R3. The first region R1 may be used to form a high voltage (HV) device, the second region R2 may be used to form a low voltage (LV) device, and the third region R3 may be used to form an ultra-low voltage (LLV) device.

A mask layer HMO is formed in the second region R2 and the third region R3 of the substrate 100. The mask layer HM0 includes, for example, a silicon oxide layer 102 and a silicon nitride layer 104. The mask layer HM0 exposes the first region R1. Next, a first gate dielectric layer 106 is formed on the substrate 100 in the first region R1. The first gate dielectric layer 106 is, for example, silicon oxide, and is formed by, for example, using the mask layer HM0 as a mask and performing a thermal oxidation process. The first gate dielectric layer 106 may be made of other materials, such as silicon nitride or high-dielectric constant materials. The first gate dielectric layer 106 may be a single layer or multiple layers. The first gate dielectric layer 106 may silicon oxide/silicon nitride/silicon oxide film stack.

Referring to FIG. 1B, the mask layer HM0 is removed to expose the surface of the substrate 100 in the second region R2 and the third region R3. During the process of removing the mask layer HM0, the first gate dielectric layer 106 may be partially removed and the thickness may be reduced. However, since the first gate dielectric layer 106 is the thickest among those in the first region R1 to the third region R3, although the thickness is reduced, there is no significant impact. Afterwards, a second gate dielectric layer 108 is formed on the substrate 100 in the second region R2 and the third region R3. The second gate dielectric layer 108 is, for example, silicon oxide, and is formed by, for example, performing a thermal oxidation process. When performing the thermal oxidation process on the second gate dielectric layer 108, the first gate dielectric layer 106 may also grow again and the thickness may increase.

Referring to FIG. 1C, a buffer layer 110 and a stop layer 112 are formed on the first gate dielectric layer 106 in the first region R1 and on the second gate dielectric layer 108 in the second region R2. The buffer layer 110 is, for example, undoped polysilicon or doped polysilicon. The stop layer 112 is, for example, silicon nitride.

Referring to FIG. 1D, a mask layer PR1 is formed on the stop layer 112. The mask layer PR1 is, for example, a patterned photoresist layer. Next, using the mask layer PR1 as a mask, the stop layer 112, the buffer layer 110, the first gate dielectric layer 106 and the second gate dielectric layer 108 are patterned, and the substrate 100 is etched to form a plurality of trenches 116.

Referring to FIG. 1E, the mask layer is removed, an insulating filling material (not shown) is formed on the stop layer 112, and the insulating filling material is also filled into a plurality of trenches 116. Thereafter, the stop layer 112 is used as a polishing stop layer, and a planarization process, such as a chemical mechanical polishing process, is performed to remove the insulating filling material from the stop layer 112 to form isolation structures ST1, ST2, ST3 and ST4 in the plurality of trenches 116.

Referring to FIG. 1F, the stop layer 112 is removed to expose the buffer layer 110 in the first region R1, the second region R2, and the third region R3.

Referring to FIG. 1G, a mask layer PR2 is formed in the first region R1 and the second region R2 of the substrate 100. The mask layer PR2 has an opening 118 exposing the third region R3 of the substrate 100. Thereafter, the mask layer PR2 is used as a mask and the substrate 100 in the third region R3 is used as a stop layer, and an etching process is performed to remove the buffer layer 110 and the second gate dielectric layer 108 from the third region R3 to expose the surface of the substrate 100 in the third region R3. Since the first region R1 and the second region R2 are covered by the mask layer PR2, the first gate dielectric layer 106 and the second gate dielectric layer 108 in the first region R1 and the second region R2 will not be etched and lose thickness.

Referring to FIG. 1H, a third gate dielectric layer 120 is formed on the substrate 100 in the third region R3. The third gate dielectric layer 120 is, for example, silicon oxide, and is formed by, for example, performing a thermal oxidation process. When performing the thermal oxidation process on the third gate dielectric layer 120, the buffer layer 110 in the second region R2 and the third region R3 might be oxidized to form the third gate dielectric layer 120. At this stage, since the first gate dielectric layer 106 and the second gate dielectric layer 108 are covered by the buffer layer 110, the first gate dielectric layer 106 and the second gate dielectric layer 108 will not be oxidized again, so the thickness thereof barely changes.

Referring to FIG. 1I, a mask layer PR3 is formed in the third region R3 of the substrate 100. The mask layer PR3 is, for example, a patterned photoresist layer. The mask layer PR3 has an opening 121. The opening 121 exposes the third gate dielectric layer 120 in the first region R1 and the second region R2. Next, the mask layer PR3 is used as a mask, and the third gate dielectric layer 120 exposed by the opening 121 is etched and removed, so that the buffer layer 110 in the first region R1 and the second region R2 is exposed. At this stage, a wet etching process may be performed to prevent the surface of the buffer layer 110 from being damaged by etching. The first gate dielectric layer 106 and the second gate dielectric layer 108 in the first region R1 and the second region R2 are covered by the buffer layer 110 without being damaged by etching. Therefore, the thicknesses of the first gate dielectric layer 106 and the second gate dielectric layer 108 will not be reduced.

Referring to FIG. 1J, a conductive layer 122 is formed in the first region R1, the second region R2, and the third region R3 of the substrate 100. The conductive layer 122 is, for example, doped polycrystalline silicon or metal silicide. The conductivity of the conductive layer 122 is higher than that of the buffer layer 110. In some embodiments, both the conductive layer 122 and the buffer layer 110 are doped polysilicon, and the doping concentration of the doped polysilicon of the conductive layer 122 is greater than the doping concentration of the doped polysilicon of the buffer layer 110.

Referring to FIG. 1K, the conductive layer 122 and the buffer layer 110 are patterned to form a first gate layer G1, a second gate layer G2, and a third gate layer G3 in the first region R1, the second region R2, and the third region R3 respectively. Thereafter, subsequent processes are continued to form source/drain electrodes, metal interconnect structures, protective layers, etc. to complete the fabrication of the semiconductor device 10A.

Referring to FIG. 1K, the semiconductor device 10A includes a first gate stack structure A1, a second gate stack structure A2, and a third gate stack structure A3. The first gate stack structure A1 includes a first gate dielectric layer 106 and a first gate layer G1. The second gate stack structure A2 includes a second gate dielectric layer 108 and a second gate layer G2. The third gate stack structure A3 includes a third gate dielectric layer 120 and a third gate layer G3.

The thickness t11 of the first gate dielectric layer 106 is greater than the thickness t12 of the second gate dielectric layer 108. The thickness t12 of the second gate dielectric layer 108 is greater than the thickness t13 of the third gate dielectric layer 120. In some embodiments, the thickness t11 ranges from 150 angstroms to 450 angstroms, the thickness t12 and t13 are less than 100 angstroms. The thickness t12 is greater than the thickness t13, and the difference between the thickness t12 and the thickness t13 is less than 30 angstroms. In some embodiments, thickness t12 is 60 angstroms and thickness t13 is 40 angstroms. In other embodiments, thickness t12 is 40 Å and thickness t13 is 20 angstroms.

Each of the first gate layer G1 and the second gate layer G2 includes a conductive layer 122 and a buffer layer 110. The buffer layer 110 of the first gate layer G1 is located between the conductive layer 122 and the first gate dielectric layer 106. The buffer layer 110 of the second gate layer G2 is located between the conductive layer 122 and the second gate dielectric layer 108. The third gate layer G3 includes the conductive layer 122 but does not include the buffer layer 110. The resistance of the buffer layer 110 is higher than the resistance of the conductive layer 122. In some embodiments, the buffer layer 110 and the conductive layer 122 are both doped polysilicon and have a lattice interface between them, and the doping concentration of the buffer layer 110 is lower than that of the conductive layer 122. The low doping concentration of the buffer layer 110 may reduce dopant diffusion into the underlying first gate dielectric layer 106 and the second gate dielectric layer 108. The thickness of the buffer layer 110 is, for example, 5% to 15% of the thickness of the conductive layer 122. The thickness t14 of the first gate layer G1 is substantially equal to the thickness t15 of the second gate layer G2. The thickness t16 of the third gate layer G3 is less than the thicknesses t14 and t15. In addition, the height of the top surface TS1 of the first gate layer G1 is substantially equal to the height of the top surface TS2 of the second gate layer G2, and the difference between them is only a few angstroms to tens of angstroms. The height of the top surface TS3 of the third gate layer G3 is lower than the heights of the top surface TS1 of the first gate layer G1 and the height of the top surface TS2 of the second gate layer G2. The height difference between the top surfaces TS3 and TS1 (TS2) is about a few hundred angstroms, for example 400 angstroms to 500 angstroms.

The first gate stack structure A1, the second gate stack structure A2 and the third gate stack structure A3 are respectively in the first active region OD1, the second active region OD2 and the third active region OD3 defined by the isolation structures ST1, ST2 and ST3.

The first top surface ss1 of the substrate 100 in the first active region OD1, the second top surface ss2 of the substrate 100 in the second active region OD2, and the third top surface ss3 of the substrate 100 in the third active region OD3 have different heights, which is related to the thickness of the buffer layer 110, the difference between the thickness t11 and the thickness t12, and the difference between the thickness t11 and the thickness t13.

The height difference between the first top surface ss1 (or the second top surface ss2) and the second top surface ss2 is about 100 angstroms to about 600 angstroms. The height difference dl between the first top surface ss1 and the third top surface ss3 is about 100 angstroms to about 600 angstroms. The height of the third top surface ss3 is lower than the height of the second top surface ss2.

The distance T1 between the first top surface ss1 of the substrate 100 in the first active region OD1 and the first bottom surface bs1 of the isolation structure ST1 is substantially equal to the distance T2 between the second top surface ss2 of the substrate 100 in the second active region OD2 and the second bottom surfaces bs2 of the isolation structure ST2. The distance T3 between the third top surface ss3 of the substrate 100 in the third active region OD3 and the third bottom surface bs3 of the isolation structure ST3 is less than the distances T1 and T2. In some embodiments, the distances T1 and T2 are about 5000 angstroms, and the distance T3 is about 4500 angstroms to 4600 angstroms.

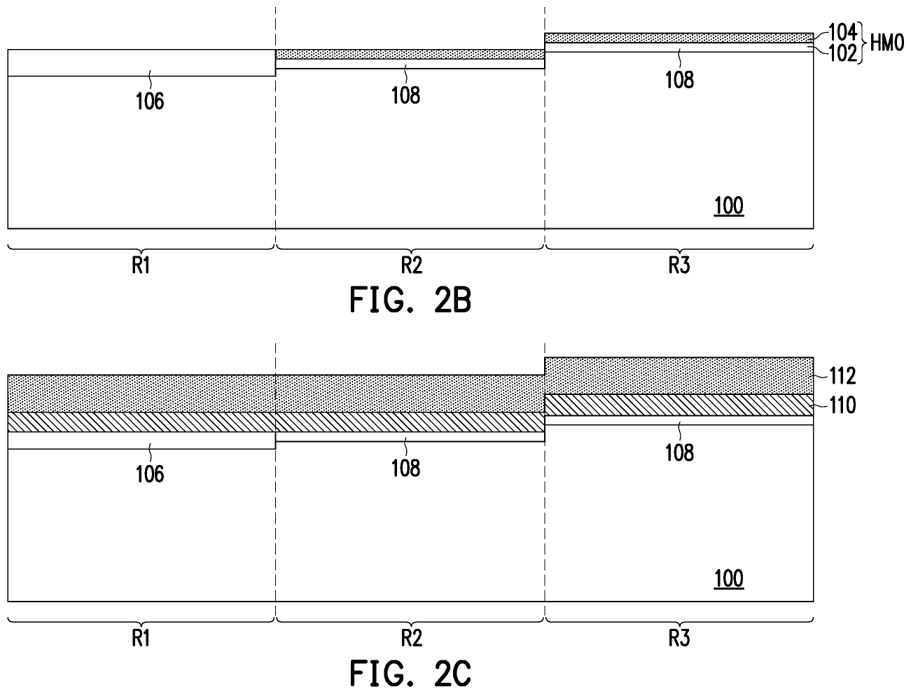

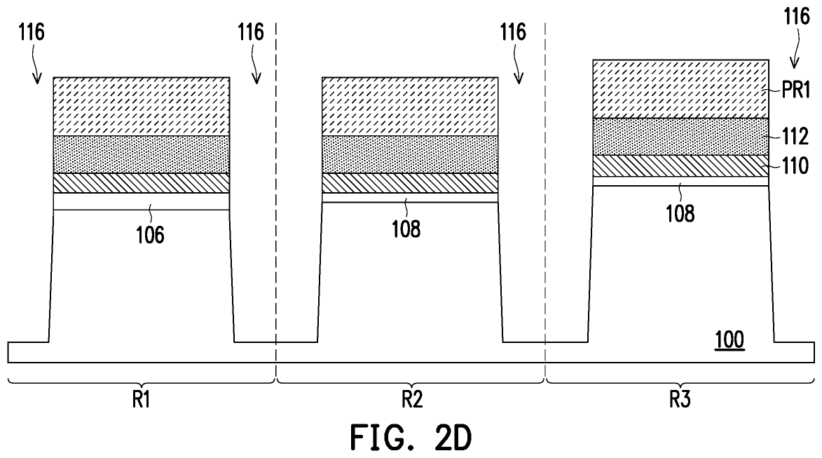

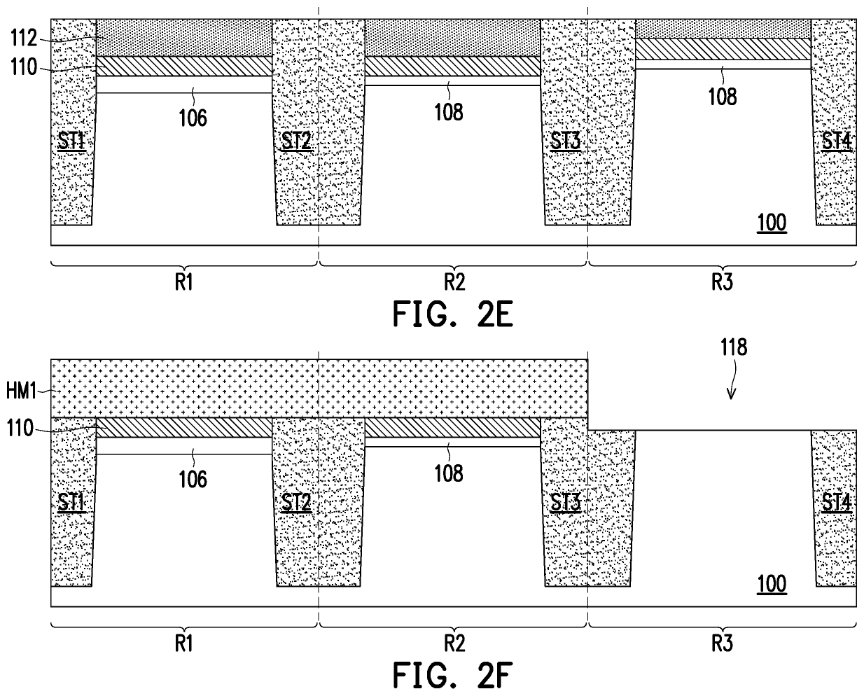

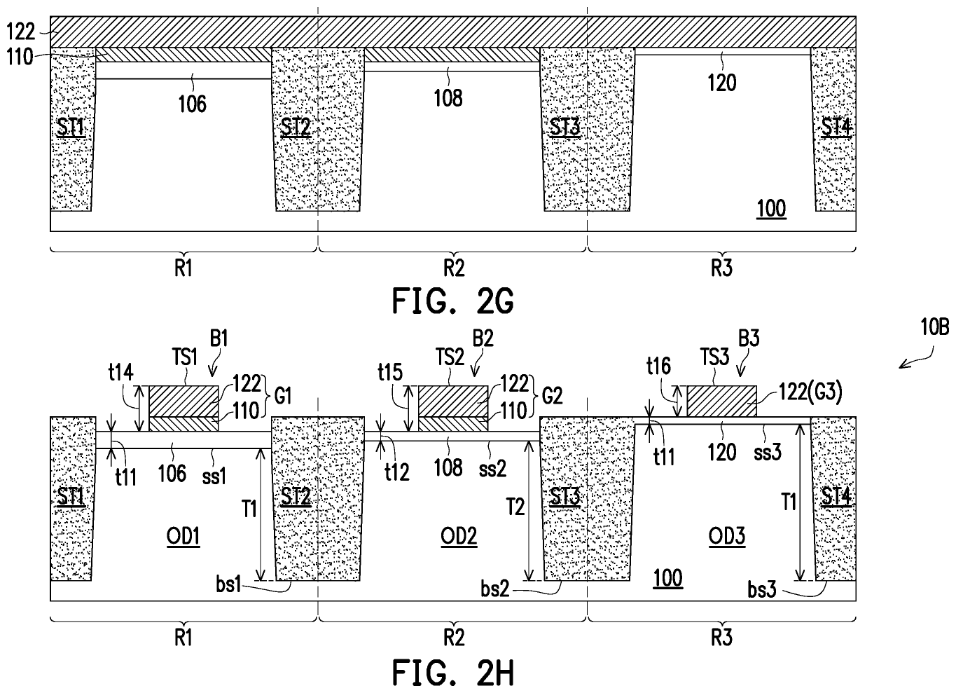

FIG. 2A to FIG. 2H show a schematic cross-sectional view of a method of fabricating a semiconductor device according to the second embodiment of the present disclosure.

The embodiment in FIG. 2A to FIG. 2H is similar to the first embodiment with reference to FIG. 1A to FIG. 1K. However, before forming the mask layer HM0, part of the substrate 100 in the first region R1 and the second region R2 is selectively removed, so that the top surface TS1 of the first gate layer G1, the top surface TS2 of the second gate layer G2, and the top surface TS3 of the third gate layer G3 formed ultimately have substantially the same height. Detailed description is provided below with reference to FIG. 2A to FIG. 2H.

Referring to FIG. 2A, a substrate 100 is provided. Next, a mask layer (not shown) is formed to cover the third region R3, and then an etching process is performed to remove part of the substrate 100. In this embodiment, the heights of the top surface S1 and the top surface S2 are substantially the same. The top surface S1 of the substrate 100 in the first region R1 and the top surface S2 of the substrate 100 in the second region R2 are lower than the top surface S3 of the substrate 100 in the third region R3.

Referring to FIG. 2B, a mask layer HM0 is formed in the second region R2 and the third region R3 of the substrate 100 according to the method of FIG. 1A in the first embodiment. The mask layer HM0 includes, for example, a silicon oxide layer 102 and a silicon nitride layer 104. The mask layer HM0 exposes the first region R1. Next, the first gate dielectric layer 106 is formed on the substrate 100 in the first region R1 according to the above method.

Referring to FIG. 2C, the mask layer HM0 is removed according to the method of FIG. 1B in the first embodiment. Afterwards, the second gate dielectric layer 108 is formed on the substrate 100 in the second region R2 and the third region R3. Thereafter, according to the method of FIG. 1C in the above embodiment, the buffer layer 110 and the stop layer 112 are formed on the first gate dielectric layer 106 in the first region R1 and on the second gate dielectric layer 108 in the second region R2.

Referring to FIG. 2D, according to the method of FIG. 1D in the first embodiment, the mask layer PR1 is formed on the stop layer 112. Then, the mask layer PR1 is used as a mask, and the stop layer 112, the buffer layer 110, the first gate dielectric layer 106 and the second gate dielectric layer 108 are patterned, and the substrate 100 is etched to form a plurality of trenches 116.

Referring to FIG. 2E, according to the method of FIG. 1E in the first embodiment, the mask layer is removed, and isolation structures ST1, ST2, ST3 and ST4 are formed in the plurality of trenches 116.

Referring to FIG. 2F, according to the method of FIG. 1F to FIG. 1G in the above embodiment, the stop layer 112 is removed, then the buffer layer 110 and the second gate dielectric layer 108 in the third region R3 are removed, and the surface of the substrate 100 in the third region R3 is exposed.

Referring to FIG. 2G, according to the method of FIG. 1H to FIG. 1J in the first embodiment, the third gate dielectric layer 120 is formed on the substrate 100 in the third region R3, and the conductive layer 122 is formed in the first region R1, the second region R2 and the third region R3 of the substrate 100.

Referring to FIG. 2H, according to the method of FIG. 1K in the first embodiment, the conductive layer 122 and the buffer layer 110 are patterned to form the first gate layer G1, the second gate layer G2 and the third gate layer G3 respectively in the first region R1, the second region R2 and the third region R3. Thereafter, subsequent processes are continued to form source/drain electrodes, metal interconnect structures, protective layers, etc. to complete the fabrication of the semiconductor device 10B.

Referring to FIG. 2H, the semiconductor device 10B includes a first gate stack structure B1, a second gate stack structure B2, and a third gate stack structure B3. The first gate stack structure B1, the second gate stack structure B2, and the third gate stack structure B3 are similar to the first gate stack structure A1, the second gate stack structure A2, and the third gate stack structure A3 respectively but slightly different from each other. The detailed description is as follows.

The thickness t11 of the first gate dielectric layer 106 is greater than the thickness t12 of the second gate dielectric layer 108. The thickness t12 of the second gate dielectric layer 108 is greater than the thickness t13 of the third gate dielectric layer 120.

Each of the first gate layer G1 and the second gate layer G2 includes the conductive layer 122 and the buffer layer 110 respectively. The buffer layer 110 of the first gate layer G1 is located between the conductive layer 122 and the first gate dielectric layer 106. The buffer layer 110 of the second gate layer G2 is located between the conductive layer 122 and the second gate dielectric layer 108. The third gate layer G3 includes the conductive layer 122 but does not include the buffer layer 110. The resistance of the buffer layer 110 is higher than the resistance of the conductive layer 122. In some embodiments, the buffer layer 110 and the conductive layer 122 are both doped polysilicon and have a lattice interface between them, and the doping concentration of the buffer layer 110 is lower than that of the conductive layer 122. The low doping concentration of the buffer layer 110 may reduce dopant diffusion into the underlying first gate dielectric layer 106 and the second gate dielectric layer 108. The thickness of the buffer layer 110 is, for example, 5% to 15% of the thickness of the conductive layer 122. The thickness t14 of the first gate layer G1 is substantially equal to the thickness t15 of the second gate layer G2. The thickness t16 of the third gate layer G3 is less than the thicknesses t14 and t15.

However, the heights of the top surface TS1 of the first gate layer G1, the top surface TS2 of the second gate layer G2, and the top surface TS3 of the third gate layer G3 are substantially the same. The height difference between the top surfaces TS3 and TS1 (TS2) is between about 0% and 2%.

The first top surface ss1 of the substrate 100 in the first active region OD1, the second top surface ss2 of the substrate 100 in the second active region OD2, and the third top surface ss3 of the substrate 100 in the third active region OD3 have different heights, which is related to the thickness of the buffer layer 110, the difference between the thickness t11 and the thickness t12, and the difference between the thickness t11 and the thickness t13. The height of the third top surface ss3 is higher than the height of the first top surface ss1, and the height of the first top surface ss1 is higher than the height of the second top surface ss2. The height difference between the third top surface ss3 and the first top surface ss1 is about 100 angstroms to about 600 angstroms. The height difference between the first top surface ss1 and the second top surface ss2 is about 300 angstroms to about 500 angstroms.

The distance T1 between the first top surface ss1 of the substrate 100 in the first active region OD1 and the first bottom surface bs1 of the isolation structure ST1 is substantially equal to the distance T2 between the second top surface ss2 of the substrate 100 in the second active region OD2 and the second bottom surface bs2 of the isolation structure ST2. The distance T3 between the third top surface ss3 of the substrate 100 in the third active region OD3 and the third bottom surface bs3 of the isolation structure ST3 is greater than the distances T1 and T2. In some embodiments, the distances T1 and T2 are about 4500 angstroms to 4600 angstroms, and the distance T3 is about 5000 angstroms.

In the above first and second embodiments, the third gate dielectric layer is formed after the isolation structure is formed. In other embodiments, the third gate dielectric layer may be formed before the isolation structure is formed. The conductive layers of the first gate layer and the second gate layer may include multiple layers, and may be formed before or after the isolation structure is formed, respectively.

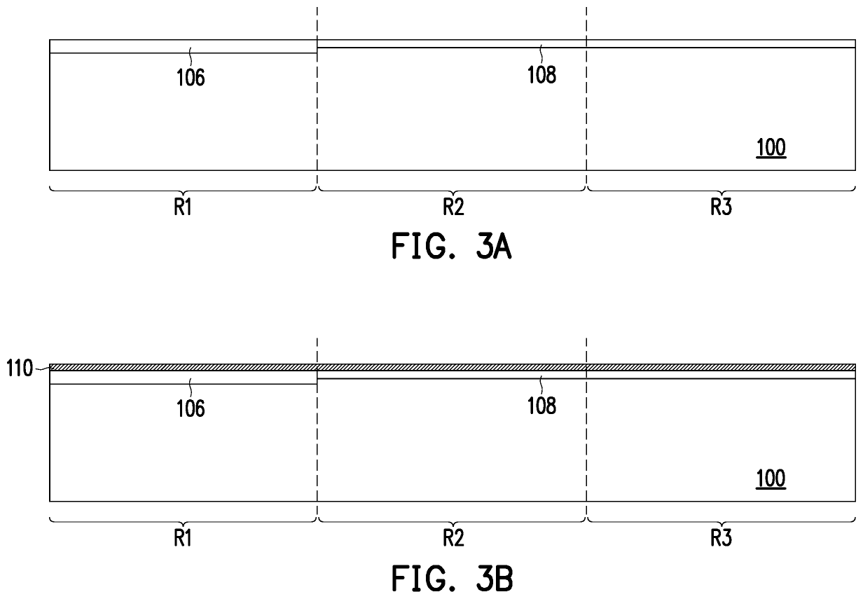

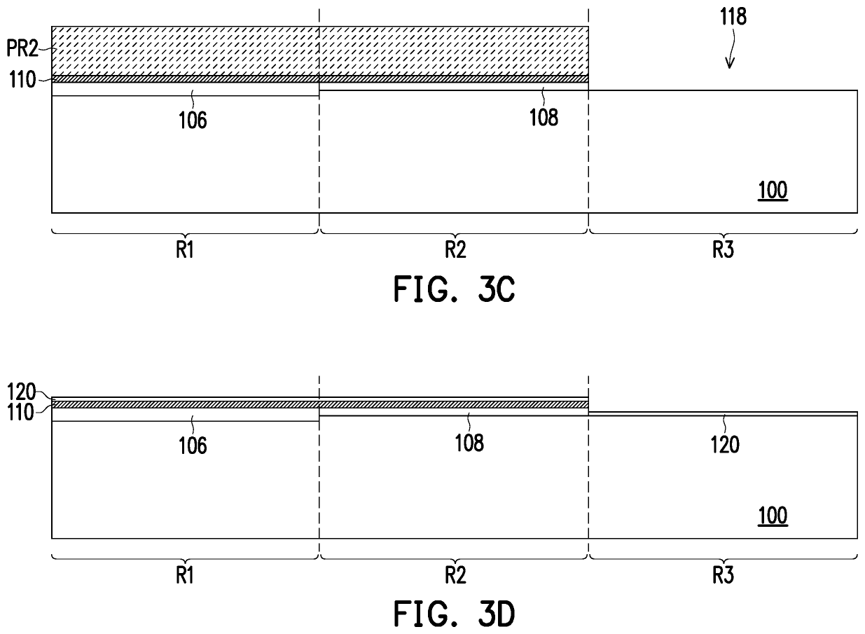

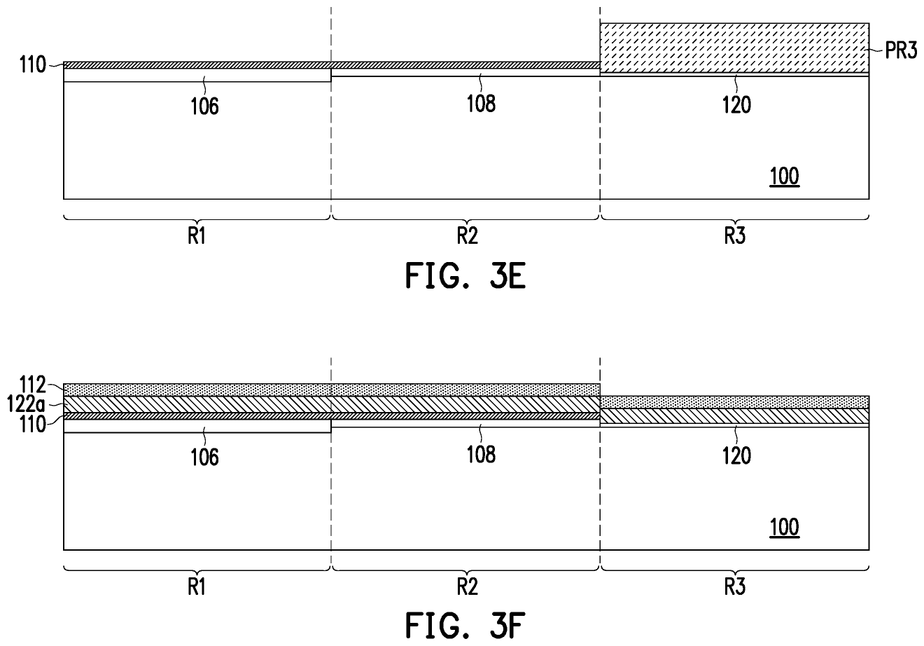

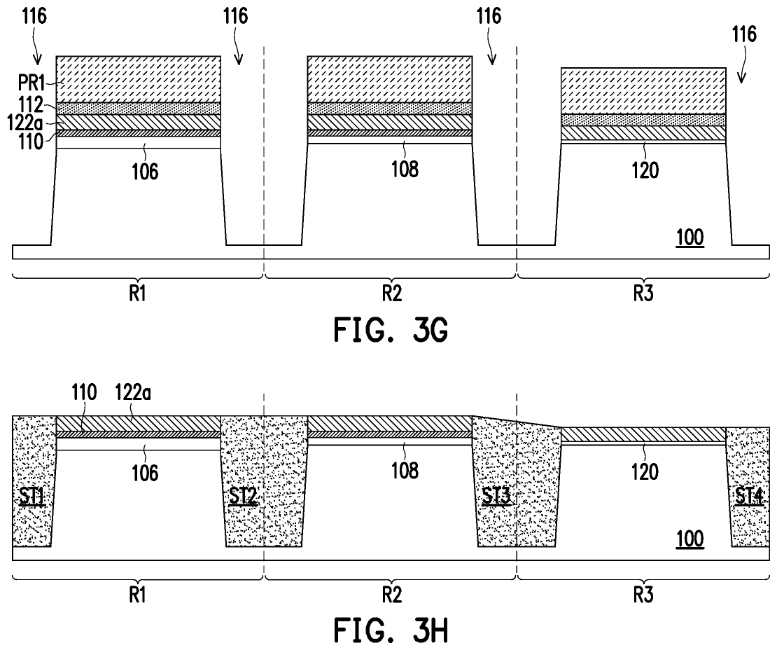

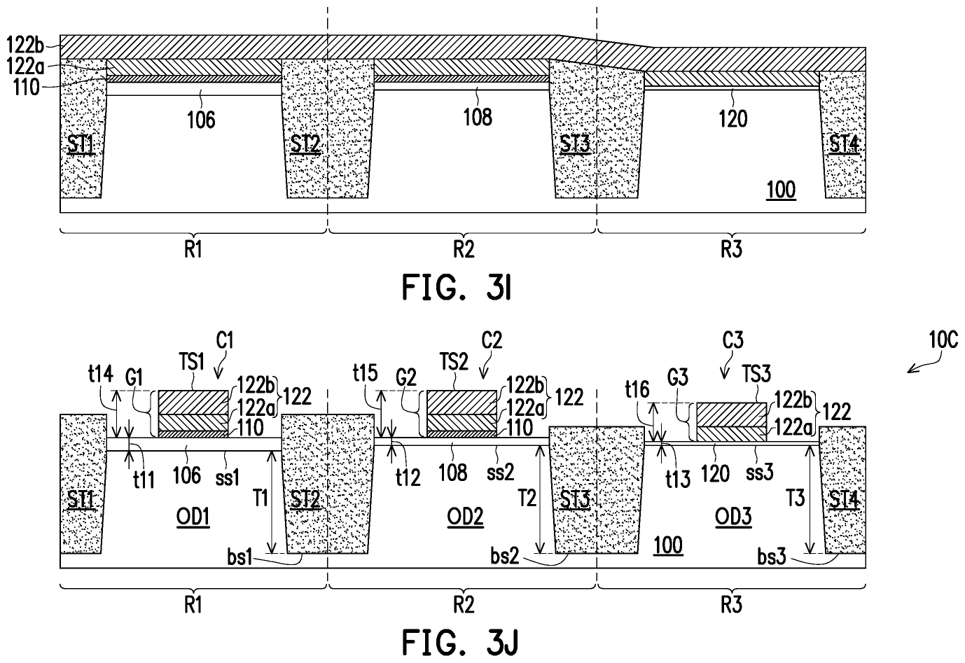

FIG. 3A to FIG. 3J show a schematic cross-sectional view of a method of fabricating a semiconductor device according to the third embodiment of the present disclosure.

Referring to FIG. 3A, according to the method of FIG. 1A and FIG. 1B in the first embodiment, the first gate dielectric layer 106 is formed in the first region R1 of the substrate 100, and the second gate dielectric layer 108 is formed in the second region R2 and the third region R3.

Referring to FIG. 3B, according to the method of FIG. 1C in the first embodiment, the buffer layer 110 is formed on the first gate dielectric layer 106 in the first region R1 and on the second gate dielectric layer 108 in the second region R2.

Referring to FIG. 3C, according to FIG. 1G in the first embodiment, the mask layer PR2 is formed in the first region R1 and the second region R2 of the substrate 100. The mask layer PR2 has an opening 118 exposing the third region R3 of the substrate 100. Thereafter, the mask layer PR2 is used as a mask and the substrate 100 of the third region R3 is used as a stop layer, an etching process is performed to remove the buffer layer 110 and the second gate dielectric layer 108 from the third region R3 to expose the surface of the substrate 100 in the third region R3.

Referring to FIG. 3D, according to FIG. 1H in the first embodiment, the third gate dielectric layer 120 is formed on the substrate 100 in the third region R3. The third gate dielectric layer 120 is, for example, silicon oxide, and is formed by, for example, performing a thermal oxidation process. When performing the thermal oxidation process on the third gate dielectric layer 120, the buffer layer 110 in the second region R2 and the third region R3 is partially oxidized to form the third gate dielectric layer 120.

Referring to FIG. 3E, according to FIG. 1I in the first embodiment, the mask layer PR3 is formed in the third region R3 of the substrate 100. The mask layer PR3 is, for example, a patterned photoresist layer. The mask layer PR3 has an opening 121. The opening 121 exposes the third gate dielectric layer 120 in the first region R1 and the second region R2. Next, the mask layer PR3 is used as a mask, the third gate dielectric layer 120 exposed by the opening 121 is etched and removed, so that the buffer layer 110 in the first region R1 and the second region R2 is exposed.

Referring to FIG. 3F, the first conductive layer 122a and the stop layer 112 are formed on the buffer layer 110 in the first region R1, the second region R2, and the third region R3. The first conductive layer 122a is, for example, doped polysilicon. The stop layer 112 is, for example, silicon nitride. In this embodiment, before forming the stop layer 112, the first conductive layer 122a is formed on the buffer layer 110 first. Referring to FIG. 3G, the mask layer PR1 is formed on the stop layer 112. The mask layer PR1 is, for example, a patterned photoresist layer. Next, the mask layer PR1 is used as a mask, and the stop layer 112, the buffer layer 110, the first gate dielectric layer 106, the second gate dielectric layer 108 and the third gate dielectric layer 120 are patterned, and the substrate 100 is etched to form the plurality of trenches 116.

Referring to FIG. 3H, the mask layer PR1 is removed. Next, an insulating filling material (not shown) is formed on the stop layer 112, and the insulating filling material is further filled into the plurality of trenches 116. Thereafter, the stop layer 112 is used as a polishing stop layer, and a planarization process, such as a chemical mechanical polishing process, is performed to remove the insulating filling material from the stop layer 112 to form isolation structures ST1, ST2, ST3 and ST4 in the plurality of trenches 116. Afterwards, the stop layer 112 is removed, and the first conductive layer 122a in the first region R1, the second region R2 and the third region R3 is removed. The conductivity of the first conductive layer 122a may be equal to or higher than that of the buffer layer 110.

Referring to FIG. 3I, after forming the isolation structures ST1, ST2, ST3 and ST4, the second conductive layer 122b is formed in the first region R1, the second region R2 and the third region R3 of the substrate 100. The second conductive layer 122b is, for example, doped polycrystalline silicon or metal silicide. The conductivity of the second conductive layer 122b is equal to or higher than the conductivity of the first conductive layer 122a. The conductivity of the second conductive layer 122b is higher than that of the buffer layer 110. In some embodiments, the first conductive layer 122a, the second conductive layer 122b and the buffer layer 110 are all doped polysilicon, and the doping concentration of the doped polysilicon of the first conductive layer 122a and the second conductive layer 122b is greater than the doping concentration of the doped polysilicon of the buffer layer 110.

Referring to FIG. 3J, the second conductive layers 122b, the first conductive layer 122a and the buffer layer 110 are patterned to form the first gate layer G1, the second gate layer G2 and the third gate layer G3 in the first region R1 and the second region R2. Thereafter, subsequent processes are continued to form source/drain electrodes, metal interconnect structures, protective layers, etc. to complete the fabrication of the semiconductor device 10C.

Referring to FIG. 3J, the semiconductor device 10C includes a first gate stack structure C1, a second gate stack structure C2, and a third gate stack structure C3. The first gate stack structure C1 includes the first gate dielectric layer 106 and the first gate layer G1. The second gate stack structure C2 includes the second gate dielectric layer 108 and the second gate layer G2. The third gate stack structure C3 includes the third gate dielectric layer 120 and the third gate layer G3. The first gate stack structure C1, the second gate stack structure C2, and the third gate stack structure C3 are respectively similar to the first gate stack structure A1, the second gate stack structure A2, and the third gate stack structure A3 but slightly different from each other. The detailed description is provided below.

The thickness t11 of the first gate dielectric layer 106 is greater than the thickness t12 of the second gate dielectric layer 108. The thickness t12 of the second gate dielectric layer 108 is greater than the thickness t13 of the third gate dielectric layer 120.

Each of the first gate layer G1 and the second gate layer G2 includes the conductive layer 122 and the buffer layer 110. The buffer layer 110 of the first gate layer G1 is located between the conductive layer 122 and the first gate dielectric layer 106. The buffer layer 110 of the second gate layer G2 is located between the conductive layer 122 and the second gate dielectric layer 108. The third gate layer G3 includes the conductive layer 122 but does not include the buffer layer 110. The resistance of the buffer layer 110 is higher than the resistance of the conductive layer 122. In some embodiments, the buffer layer 110 and the conductive layer 122 are both doped polysilicon and have a lattice interface between them, and the doping concentration of the buffer layer 110 is lower than that of the conductive layer 122. The low doping concentration of the buffer layer 110 may reduce dopant diffusion into the underlying first gate dielectric layer 106 and the second gate dielectric layer 108. The thickness of the buffer layer 110 is, for example, 5% to 15% of the thickness of the conductive layer 122. The thickness t14 of the first gate layer G1 is substantially equal to the thickness t15 of the second gate layer G2. The thickness t16 of the third gate layer G3 is less than the thicknesses t14 and t15. In addition, the height of the top surface TS1 of the first gate layer G1 is substantially equal to the height of the top surface TS2 of the second gate layer G2, and the height difference between them is only a few angstroms to tens of angstroms. The height of the top surface TS3 of the third gate layer G3 is lower than the height of the top surface TS1 of the first gate layer G1 and the height of the top surface TS2 of the second gate layer G2. The height difference between the top surfaces TS3 and TS1 (TS2) is about a few hundred angstroms, for example 400 angstroms to 500 angstroms.

The first gate stack structure A1, the second gate stack structure A2 and the third gate stack structure A3 are respectively in the first active region OD1, the second active region OD2 and the third active region OD3 defined by the isolation structures ST1, ST2 and ST3.

The first top surface ss1 of the substrate 100 in the first active region OD1, the second top surface ss2 of the substrate 100 in the second active region OD2, and the third top surface ss3 of the substrate 100 in the third active region OD3 have different heights. The height of the third top surface ss3. The height difference between the third top surface ss3 and the first top surface ss1 is about 100 angstroms to about 600 angstroms. The height difference between the third top surface ss3 and the second top surface ss2 is about 100 angstroms to about 600 angstroms.

The distance T1 between the first top surface ss1 of the substrate 100 in the first active region OD1 and the first bottom surface bs1 of the isolation structure ST1 is substantially equal to the distance T2 between the second top surface ss2 of the substrate 100 in the second active region OD2 and the second bottom surfaces bs2 of the isolation structure ST2. The distance T3 between the third top surface ss3 of the substrate 100 in the third active region OD3 and the third bottom surface bs3 of the isolation structure ST3 is less than the distances T1 and T2. In some embodiments, the distances T1 and T2 are about 5000 angstroms, and the distance T3 is about 4500 angstroms to about 4600 angstroms.

However, the conductive layer 122 of the first gate layer G1, the second gate layer G2 and the third gate layer G3 includes the first conductive layer 122a and the second conductive layer 122b. The conductivity of the second conductive layer 122b is equal to or higher than the conductivity of the first conductive layer 122a. The conductivity of the second conductive layer 122b is higher than that of the buffer layer 110. In some embodiments, the second conductive layers 122b and 122a and the buffer layer 110 are both doped polysilicon, and the doping concentration of the doped polysilicon of the second conductive layers 122b and 122a is greater than the doping concentration of the doped polysilicon of the buffer layer 110.

In the above embodiment, referring to FIG. 3A to FIG. 3D, the first gate dielectric layer 106 is formed in the first region R1, and then the second gate dielectric layer 108 is formed in the second region R2 and the third region R3. Afterwards, the second gate dielectric layer 108 in the third region R3 is removed, and then the third gate dielectric layer 120 is formed in the third region R3. However, in another embodiment, the first gate dielectric layer 106 may also be formed in the first region R1, and then the third gate dielectric layer 120 may be formed in the second region R2 and the third region R3. Thereafter, the third gate dielectric layer 120 in the second region R2 is removed, and then the second gate dielectric layer 108 is formed in the second region R2.

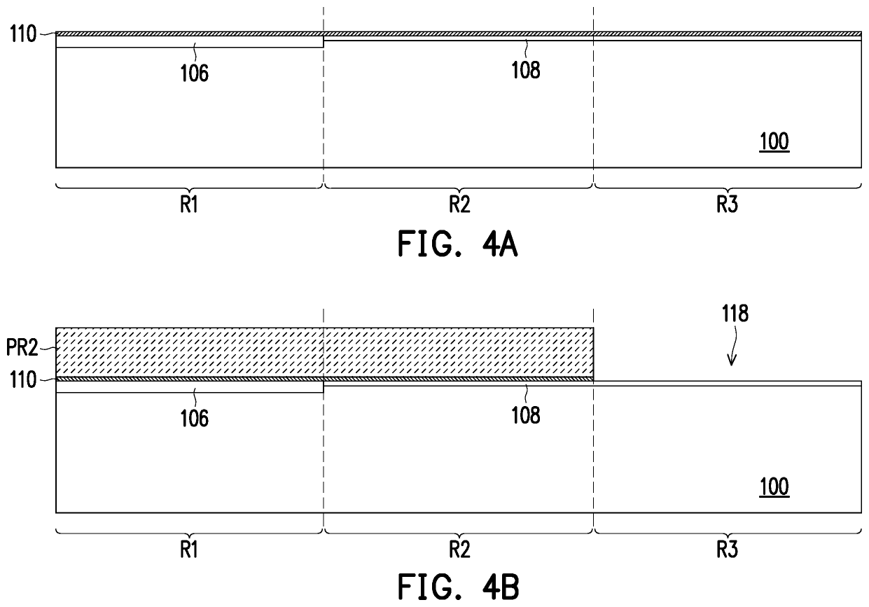

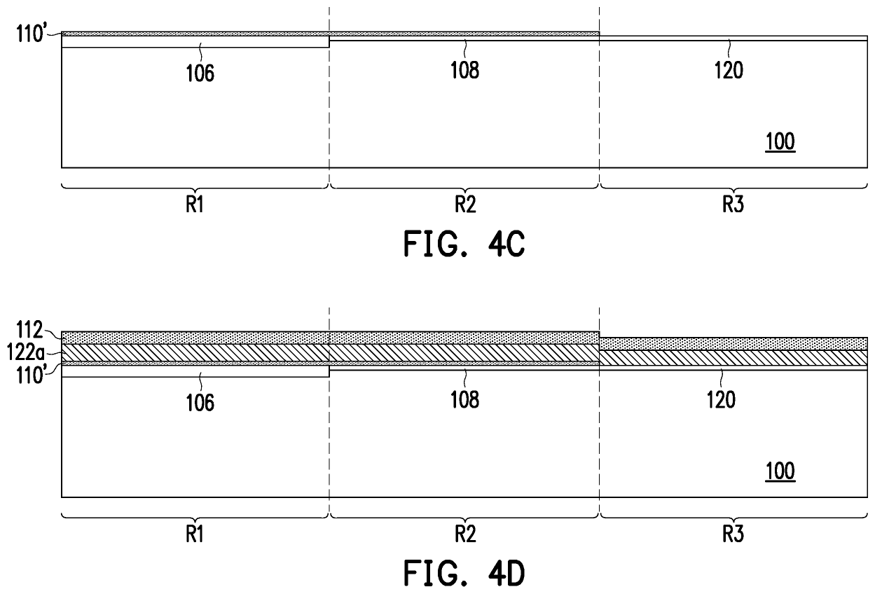

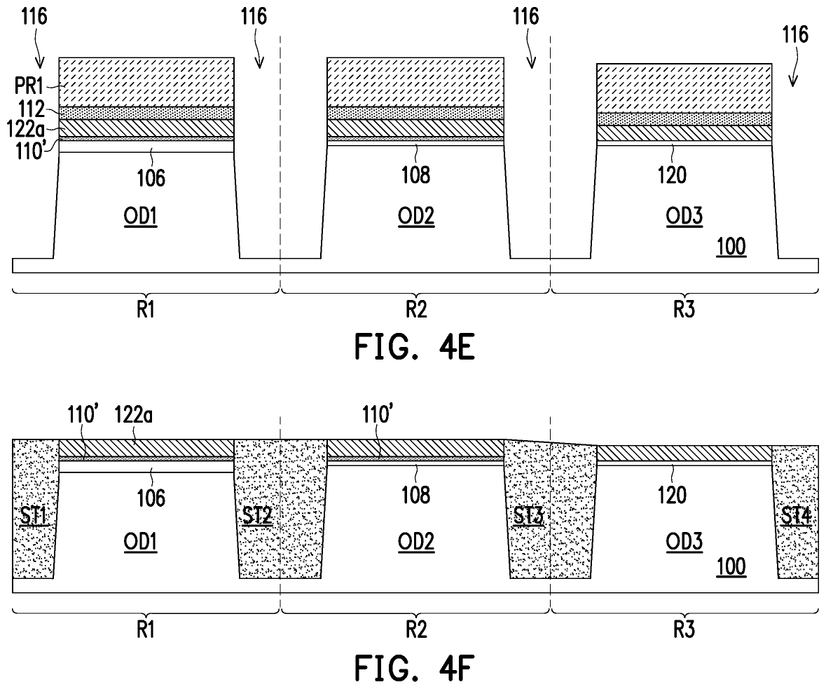

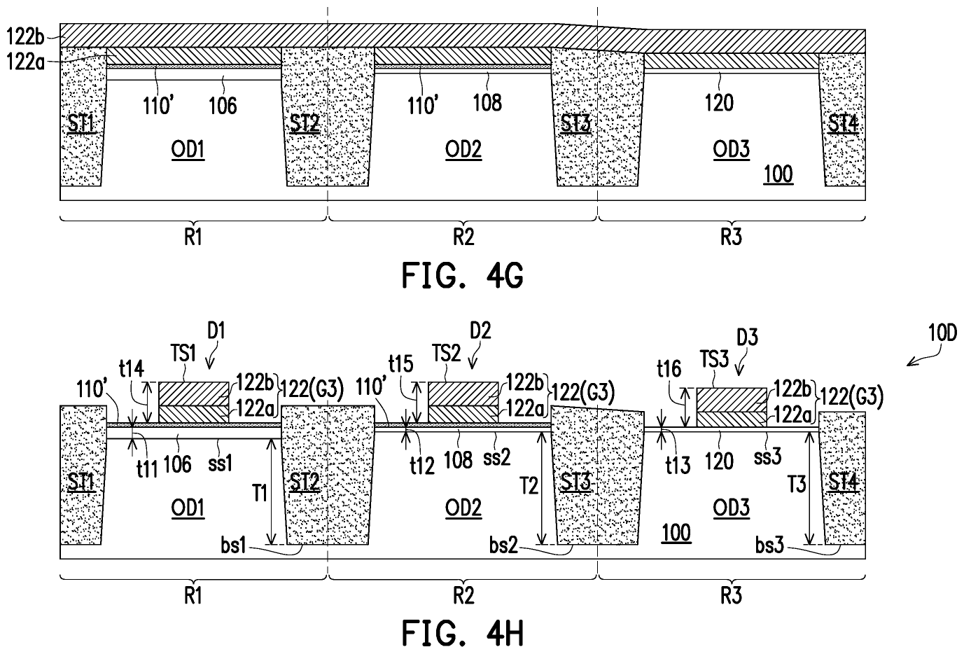

Furthermore, in the above embodiment, the buffer layer 110 is partially oxidized. In other embodiments, the buffer layer may be completely oxidized. FIG. 4A to FIG. 4H show a schematic cross-sectional view of a method of fabricating a semiconductor device according to the fourth embodiment of the present disclosure.

Referring to FIG. 4A, according to the method according to FIG. 3A and FIG. 3B in the above third embodiment, the first gate dielectric layer 106 is formed in the first region R1 of the substrate 100, and the second gate dielectric layer 108 is formed in the second region R2 and the third region R3. Thereafter, the buffer layer 110 is formed in the first region R1, the second region R2 and the third region R3.

Referring to FIG. 4B, according to the method in FIG. 3C in the above third embodiment, the mask layer PR2 is formed in the first region R1 and the second region R2 of the substrate 100. The mask layer PR2 has an opening 118 exposing the third region R3 of the substrate 100. Thereafter, the mask layer PR2 is used as a mask and the substrate 100 in the third region R3 is used as a stop layer; an etching process is performed to remove the buffer layer 110 and the second gate dielectric layer 108 from the third region R3 to expose the surface of the substrate 100 in the third region R3.

Referring to FIG. 4C, the third gate dielectric layer 120 is formed on the substrate 100 in the third region R3. The third gate dielectric layer 120 is, for example, silicon oxide, and is formed through, for example, a thermal oxidation process. When performing the thermal oxidation process on the third gate dielectric layer 120, the buffer layer 110 in the second region R2 and the third region R3 is completely oxidized to form the buffer layer 110′. The buffer layer 110′ is, for example, silicon oxide. The buffer layer 110′ may also be called an additional gate dielectric layer 110′.

Referring to FIG. 4D, the first conductive layer 122a and the stop layer 112 are formed on the additional gate dielectric layer 110′ in the first region R1, the second region R2, and the third region R3. The first conductive layer 122a is, for example, doped polysilicon. The stop layer 112 is, for example, silicon nitride.

Referring to FIG. 4E, the mask layer PR1 is formed on the stop layer 112. Next, the mask layer PR1 is used as a mask, the stop layer 112, the additional gate dielectric layer 110′, the first gate dielectric layer 106, the second gate dielectric layer 108 and the third gate dielectric layer 120 are patterned, and the substrate 100 is etched to form a plurality of trenches 116.

Referring to FIG. 4F, the mask layer PR1 is removed. Next, isolation structures ST1, ST2, ST3 and ST4 are formed between the plurality of trenches 116. Afterwards, the stop layer 112 is removed, exposing the first conductive layer 122a in the first region R1, the second region R2 and the third region R3. The conductivity of the first conductive layer 122a is higher than that of the additional gate dielectric layer 110′.

Referring to FIG. 4G, the second conductive layer 122b is formed in the first region R1, the second region R2, and the third region R3 of the substrate 100. The second conductive layer 122b is, for example, doped polycrystalline silicon or metal silicide. The conductivity of the second conductive layer 122b is equal to or higher than the first conductive layer 122a. The conductivity of the second conductive layer 122b is higher than that of the additional gate dielectric layer 110′. In some embodiments, the additional gate dielectric layer 110′ is silicon oxide, the second conductive layers 122b and 122a are both doped polysilicon, and the doping concentration of the doped polysilicon of the second conductive layers 122b and 122a is greater than the doping concentration of doped polysilicon of the buffer layer 110.

Referring to FIG. 4H, the second conductive layers 122b and 122a and the buffer layer 110′ are patterned to form the first gate layer G1 and the additional gate dielectric layer 110′ as well as the second gate layer G2 and the additional gate dielectric layer 110′ in the first region R1 and the second region R2 respectively, and form the third gate layer G3 in the third region R3. Thereafter, subsequent processes are continued to form, for example, source/drain electrodes, metal interconnect structures, protective layers, etc. to complete the fabrication of the semiconductor device 10D.

Referring to FIG. 4H, the semiconductor device 10D includes the first gate stack structure D1, the second gate stack structure D2, and the third gate stack structure D3. The first gate stack structure A1 includes the first gate dielectric layer 106, the additional gate dielectric layer 110′ and the first gate layer G1. The second gate stack structure A2 includes the second gate dielectric layer 108, the additional gate dielectric layer 110′ and the second gate layer G2. The third gate stack structure A3 includes the third gate dielectric layer 120 and the third gate layer G3. The first gate stack structure D1, the second gate stack structure D2, and the third gate stack structure D3 are respectively similar to the first gate stack structure C1, the second gate stack structure C2, and the third gate stack structure C3 but slightly different from each other. The detailed description is as follows.

The first gate stack structure D1 includes the first gate dielectric layer 106, the additional gate dielectric layer 110′ and the first gate layer G1. The second gate stack structure D2 includes the second gate dielectric layer 108, the additional gate dielectric layer 110′ and the second gate layer G2. The third gate stack structure D3 includes the third gate dielectric layer 120 and the third gate layer G3.

The thickness t11 of the first gate dielectric layer 106 is greater than the thickness t12 of the second gate dielectric layer 108. The thickness t12 of the second gate dielectric layer 108 is greater than the thickness t13 of the third gate dielectric layer 120.

The additional gate dielectric layer 110′ of the first gate stack structure D1 is between the first gate dielectric layer 106 and the first gate layer G1. The additional gate dielectric layer 110′ of the second gate stack structure D2 is between the second gate dielectric layer 108 and the second gate layer G2. The third gate stack structure D3 does not include the additional gate dielectric layer 110′. The additional gate dielectric layer 110′ is completely oxidized from the buffer layer 110, and the material of the additional gate dielectric layer 110′ is, for example, silicon oxide. The thickness of the additional gate dielectric layer 110′ of the first gate stack structure D1 is less than the thickness t11, and equal to the thickness of the additional gate dielectric layer 110′ of the second gate stack structure D2.

The conductive layers 122 of the first gate layer G1, the second gate layer G2, and the third gate layer G3 each include the first conductive layer 122a and the second conductive layer 122b. The conductivity of the second conductive layer 122b is equal to or higher than the conductivity of the first conductive layer 122a. The conductivity of the second conductive layer 122b is higher than the conductivity of the additional gate dielectric layer 110′. In some embodiments, the second conductive layers 122b and 122a are both doped polysilicon and have a lattice interface between them. The doping concentration of the second conductive layer 122b may be greater than or equal to the doping concentration of the first conductive layer 122a.

The thickness t14 of the first gate layer G1, the thickness t15 of the second gate layer G2, and the thickness t16 of the third gate layer G3 are substantially the same.

The heights of the top surface TS1 of the first gate layer G1, the top surface TS2 of the second gate layer G2, and the top surface TS3 of the third gate layer G3 are substantially the same. The height difference between the top surfaces TS3 and TS1 (TS2) is between about 1% and 2%. The height of the first top surface ss1 of the substrate 100 in the first active region OD1, the height of the second top surface ss2 of the substrate 100 in the second active region OD2, and the height of the third top surface ss3 of the substrate 100 in the third active region OD3 are substantially the same.

In the above embodiment, referring to FIG. 4A to FIG. 4C, the first gate dielectric layer 106 is formed in the first region R1, and then the second gate dielectric layer 108 is formed in the second region R2 and the third region R3. Afterwards, the second gate dielectric layer 108 in the third region R3 is removed, and then the third gate dielectric layer 120 is formed in the third region R3. However, in another embodiment, the first gate dielectric layer 106 may also be formed in the first region R1, and then the third gate dielectric layer 120 may be formed in the second region R2 and the third region R3. Afterwards, the third gate dielectric layer 120 in the second region R2 is removed, and then the second gate dielectric layer 108 is formed in the second region R2.

In the present disclosure, a semiconductor device a having gate dielectric layers with multiple various (e.g., two or three) thicknesses may be formed for application in high voltage (HV) devices, low voltage (LV) devices, and extra low voltage (LLV) devices which have different operating voltages. Among them, the thickness of the gate dielectric layer of high-voltage (HV) devices is the thickest, and the thickness of the gate dielectric layer of ultra-low voltage (LLV) devices is the thinnest. In particular, the minimum thickness of these gate dielectric layers may be extremely thin, for example, 10 angstroms to 40 angstroms. Furthermore, the semiconductor device with gate dielectric layers of various thicknesses of the present disclosure may be applied to the peripheral regions of various memory devices. Applicable memory devices may include AND, NAND, NOR, or other memory devices.

Based on the above, the present disclosure adds a buffer layer between the gate conductive layer and the gate dielectric layer to block oxygen diffusion, prevent the previously formed gate dielectric layer from being oxidized, and may serve as a part of the gate layer. Furthermore, the buffer layer may be completely oxidized and serve as an additional gate dielectric layer. Furthermore, the present disclosure makes it possible to avoid the thickness loss of the gate dielectric layer that is already formed during the fabrication process, thereby accurately forming three gate dielectric layers with significant thickness differences. In addition, embodiments of the present disclosure may be integrated with the self-aligned shallow trench isolation structure process and reduce the number of chemical mechanical polishing processes to reduce manufacturing costs.

What is claimed is:

1. A semiconductor device, comprising:
a substrate comprising a first region, a second region and a third region;
a first gate stack structure located on the substrate in the first region, wherein the first gate stack structure comprises a first gate layer and a first gate dielectric layer;
a second gate stack structure located on the substrate in the second region, wherein the second gate stack structure comprises a second gate layer and a second gate dielectric layer; and
a third gate stack structure located on the substrate in the third region, wherein the third gate stack structure comprises a third gate layer and a third gate dielectric layer,
wherein a thickness of the first gate dielectric layer is greater than a thickness of the second gate dielectric layer, the thickness of the second gate dielectric layer is greater than a thickness of the third gate dielectric layer,
wherein thicknesses of the first gate layer and the second gate layer are respectively greater than a thickness of the third gate layer.

2. The semiconductor device according to claim 1, wherein:
the first gate layer comprises a first gate conductive layer and a first buffer layer, wherein the first buffer layer is between the first gate conductive layer and the first gate dielectric layer; and
the second gate layer comprises a second gate conductive layer and a second buffer layer, wherein the second buffer layer is between the second gate conductive layer and the second gate dielectric layer.

3. The semiconductor device according to claim 2, wherein resistances of the first buffer layer and the second buffer layer are higher than those of the first gate conductive layer and the second gate conductive layer.

4. The semiconductor device according to claim 3, wherein the first buffer layer and the second buffer layer are made of materials comprising doped polycrystalline silicon or silicon oxide.

5. The semiconductor device according to claim 3, wherein a height of a top surface of the third gate layer is lower than a height of a top surface of the first gate layer, and the height of the top surface of the first gate layer is equal to a height of a top surface of the second gate layer.

6. The semiconductor device according to claim 5, wherein a height of a third top surface of the substrate in the third region is lower than a height of a first top surface of the substrate in the first region, and the height of the first top surface of the substrate in the first region is equal to a height of a second top surface of the substrate in the second region.

7. The semiconductor device according to claim 5, wherein a height of the top surface of the third gate layer is equal to a height of the top surface of the first gate layer, and is equal to a height of the top surface of the second gate layer.

8. The semiconductor device according to claim 7, wherein the first gate layer, the second gate layer and the third gate layer respectively comprise a first conductive layer and a second conductive layer on the first conductive layer.

9. The semiconductor device according to claim 3, wherein a height of a top surface of the third gate layer is equal to a height of a top surface of the first gate layer, and is equal to a height of a top surface of the second gate layer.

10. The semiconductor device according to claim 9, wherein a height of a third top surface of the substrate in the third region is higher than a height of a first top surface of the substrate in the first region, and the height of the first top surface of the substrate in the first region is equal to a height of a second top surface of the substrate in the second region.

11. The semiconductor device according to claim 9, wherein a height of a third top surface of the substrate in the third region is equal to a height of a first top surface of the substrate in the first region, and is equal to a height of a second top surface of the substrate in the second region.

12. The semiconductor device according to claim 11, further comprising:
a first additional gate dielectric layer disposed between the first gate dielectric layer and the first gate layer; and
a second additional gate dielectric layer disposed between the second gate dielectric layer and the second gate layer,
the third gate dielectric layer comprising a single dielectric layer,
wherein the thickness of the first gate dielectric layer is greater than a thickness of the first additional gate dielectric layer,
the thickness of the first additional gate dielectric layer is equal to a thickness of the second additional gate dielectric layer.

13. A method for fabricating a semiconductor device, comprising:
providing a substrate, the substrate comprising a first region, a second region and a third region;
forming a first gate dielectric layer on the substrate in the first region;
forming a second gate dielectric layer on the substrate in the second region and the third region;
forming a buffer layer on the first gate dielectric layer in the first region and on the second gate dielectric layer in the second region;
forming a third gate dielectric layer on the substrate in the third region;
forming a conductive layer on the buffer layer in the first region, the second region, and the third gate dielectric layer in the third region; and
patterning the conductive layer and the buffer layer to form a first gate layer in the first region, a second gate layer in the second region, and a third gate layer in the third region.

14. The method for fabricating the semiconductor device according to claim 13, wherein:
a thickness of the first gate dielectric layer is larger than a thickness of the second gate dielectric layer, and the thickness of the second gate dielectric layer is larger than a thickness of the third gate dielectric layer,
thicknesses of the first gate layer and the second gate layer are respectively greater than a thickness of the third gate layer.

15. The method for fabricating the semiconductor device according to claim 13, wherein a height of a top surface of the third gate layer is lower than a height of a top surface of the first gate layer, and the height of the top surface of the first gate layer is equal to a height of a top surface of the second gate layer.

16. The method for fabricating the semiconductor device according to claim 13, wherein:
a first top surface of the substrate in the first region and a second top surface of the substrate in the second region are lower than a third top surface of the substrate in the third region,
wherein the first gate dielectric layer is formed on the first top surface of the substrate, the second gate dielectric layer is formed on the second top surface of the substrate, and the third gate dielectric layer is formed on the third top surface of the substrate.

17. The method for fabricating the semiconductor device according to claim 13, further comprising:
forming a plurality of isolation structures in the first region, the second region and the third region of the substrate, wherein the conductive layer covers the plurality of isolation structures.

18. The method for fabricating the semiconductor device according to claim 13, wherein forming the conductive layer comprises:
forming a first conductive layer on the buffer layer in the first region and the second region, and the third gate dielectric layer in the third region; and
forming a second conductive layer on the first conductive layer in the first region, the second region and the third region.

19. The method for fabricating the semiconductor device according to claim 18, further comprising:
forming a plurality of isolation structures in the substrate in the first region, the second region and the third region, wherein the plurality of isolation structures pass through the first conductive layer, and wherein the second conductive layer covers the plurality of isolation structures.

20. The method for fabricating the semiconductor device according to claim 18, wherein:
forming the third gate dielectric layer comprises performing a thermal oxidation process, and the thermal oxidation process further oxidizes the buffer layer to form a first additional gate dielectric layer on the first gate dielectric layer in the first region, and form a second additional gate dielectric layer on the second gate dielectric layer in the second region.
